(19) United States
(12) Patent Application Publication
(10) Pub. No.: US 2006/0081467 A1
(43) Pub. Date: Apr. 20, 2006

(54) Systems and methods for magnetron deposition

(76) Inventors: Makoto Nagashima, Tokyo (JP); Dominik Schmidt, Stanford, CA (US)

Correspondence Address: TRAN & ASSOCIATES, 6768 MEADOW VISTA CT., SAN JOSE, CA, 95135, US

(21) Appl. No.: 10/966,385

(22) Filed: Oct. 15, 2004

(51) Int. Cl. C23C 14/00

(52) U.S. Cl. 204/298.16; 204/298.07

(57) ABSTRACT

Systems and methods are disclosed for face target sputtering to fabricate semiconductors by an air-tight chamber in which an inert gas is admittable and exhaustible; a first cylindrical target plate; inner and outer cylindrical magnets respectively disposed adjacent to the cylindrical target plate such that magnet poles of different polarities face each other across said plasma region thereby to establish a magnetic field covering the target plate; and a substrate holder adapted to hold a substrate on which an alloyed thin film is to be deposited.

### BACKGROUND

FTS (Facing Target Sputtering) method is a semiconductor fabrication technique that provides high density plasma, high deposition rate at low working gas pressure to form high quality thin film. In a facing target type of sputtering apparatus, at least a pair of target planes are arranged to face each other in a vacuum vessel, and magnetic fields are generated perpendicularly to the target planes for confining plasma in the space between the facing target planes. The substrate is arranged so as to be positioned at the side of the space so that films are produced on the substrate by sputtering.

As discussed in U.S. Pat. No. 6,156,172, a typical FTS apparatus includes a vacuum vessel for defining therein a confined vacuum chamber, an air exhausting unit having a vacuum pump system to cause a vacuum via an outlet, and a gas supplying unit for introducing sputtering gas into the vacuum vessel. A pair of target portions are arranged in the vacuum vessel in such a manner that a pair of rectangular shape cathode targets face each other so as to define a predetermined space therebetween.

Another FTS apparatus discussed in the '172 patent confines sputtering plasma in a box type of plasma space using a pair permanent magnets so as to face N and S-pole generate magnetic flux circulating perpendicularly the outside space of the first facing targets which defines facing target mode in combination with electric fields perpendicular to target planes in plasma space. The pair of magnets generate a conventional magnetron mode with a closed magnetic flux from the pole of magnets in the vicinity of the outside area of the pair of target planes in addition to the facing target mode. The cathodes of all the targets are arranged so as to recoil and confine the electrons into the plasma space by the aid of both the facing target mode and the magnetron mode.

To improve the deposition speed of the equipment, the '172 patent discloses an FTS apparatus which includes: an arrangement for defining box-type plasma units supplied therein with sputtering gas mounted on outside wall-plates of a closed vacuum vessel; at least a pair of targets arranged to be spaced apart from and face one another within the box-type plasma unit, with each of the targets having a sputtering surface thereof; a framework for holding five planes of the targets or a pair of facing targets and three plate-like members providing the box-type plasma unit so as to define a predetermined space apart from the pair of facing targets and the plate-like members, which framework is capable of being removably mounted on the outside walls of the vacuum vessel with vacuum seals; a holder for the target having conduits for a coolant; an electric power source for the targets to cause sputtering from the surfaces of the targets; permanent magnets arranged around each of the pair of targets for generating at least a perpendicular magnetic field extending in a direction perpendicular to the sputtering surfaces of the facing targets; devices for containing the permanent magnets with target holders, removably mounted on the framework; and a substrate holder at a position adjacent the outlet space of the sputtering plasma unit in the vacuum vessel.

### SUMMARY

Systems and methods are disclosed for face target sputtering to fabricate semiconductors by an air-tight chamber in which an inert gas is admittable and exhaustible; a first cylindrical target plate; inner and outer cylindrical magnets respectively disposed adjacent to the cylindrical target plate such that magnet poles of different polarities face each other across said plasma region thereby to establish a magnetic field covering the target plate; and a substrate holder adapted to hold a substrate on which an alloyed thin film is to be deposited.

Advantages of the above system may include one or more of the following. The above configuration provides symmetry and scalability. While conventional FTS systems is constrained in size because the magnetic field and process pressure change depending on the distance between the plates, the above circular system can be expanded since the distance between the two circular target plates can be kept constant while both of their diameters are increased. For example, while a conventional FTS system could uniformly cover only a one-inch area with a four-inch target plate separation, the circular system can cover a 12-inch area with the same four-inch target plate separation. Such increased coverage increases the deposition rate to increase productivity and thus lowers operating cost. The compact and simplified configuration also increases reliability.

### BRIEF DESCRIPTION OF THE FIGURES

In order that the manner in which the above-recited and other advantages and features of the invention are obtained, a more particular description of the invention briefly described above will be rendered by reference to specific embodiments thereof, which are illustrated, in the appended drawings. Understanding that these drawings depict only typical embodiments of the invention and are not therefore to be considered to be limiting of its scope, the invention will be described and explained with additional specificity and detail through the use of the accompanying drawings in which:

FIG. 1A shows one embodiment of an apparatus for fabricating semiconductor.

FIG. 1B shows magnet arrangement in FIG. 1A to provide a symmetrical source.

FIG. 1C shows the system of FIG. 1B with a plurality of moving magnets.

FIG. 1D shows the system of FIG. 1B with an oxygen trap.

FIG. 1E shows a cross-type facing magnetron.

FIG. 1F shows an exemplary embodiment of a target material.

FIG. 2 is an exemplary electron distribution chart.

FIG. 3 shows another embodiment of a FTS unit.

### DESCRIPTION

Referring now to the drawings in greater detail, there is illustrated therein structure diagrams for a semiconductor processing system and logic flow diagrams for processes a system will utilize to deposit a memory device at low temperature, as will be more readily understood from a study of the diagrams.

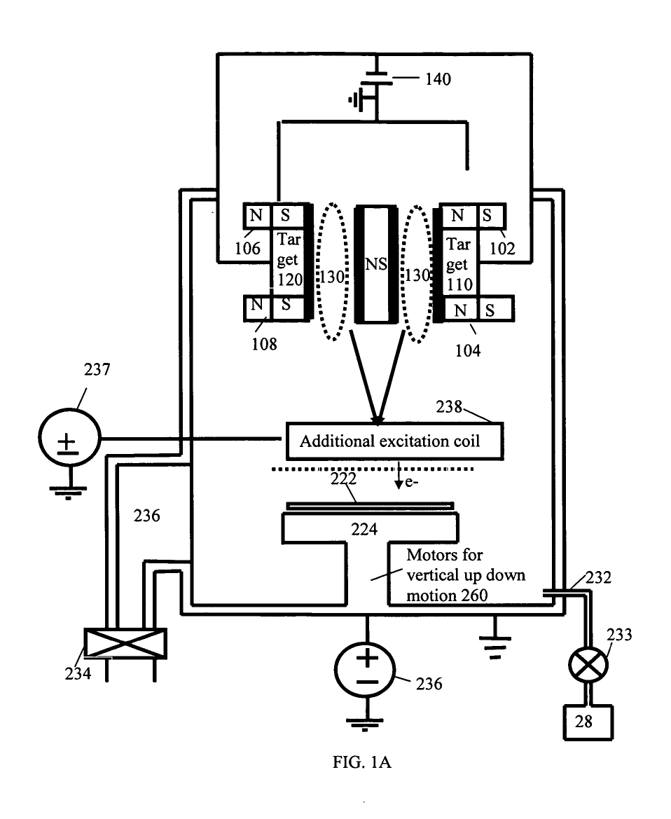

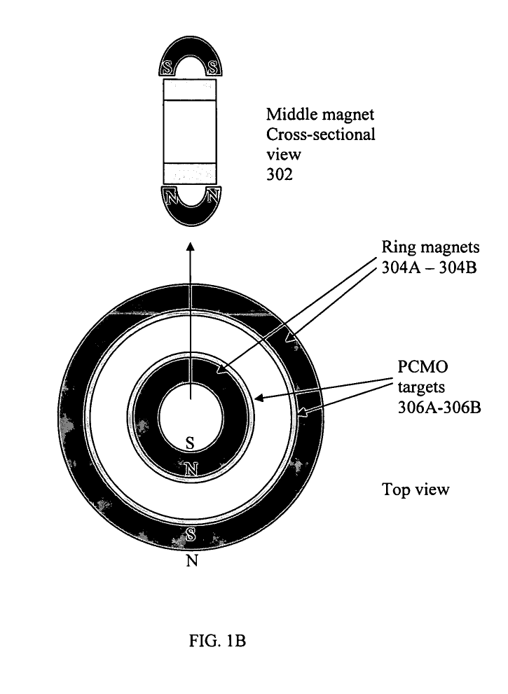

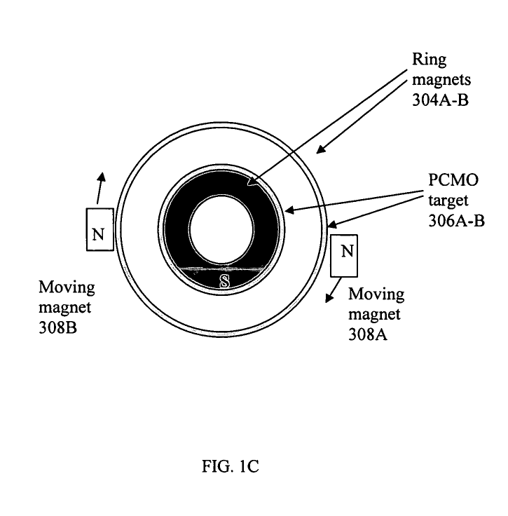

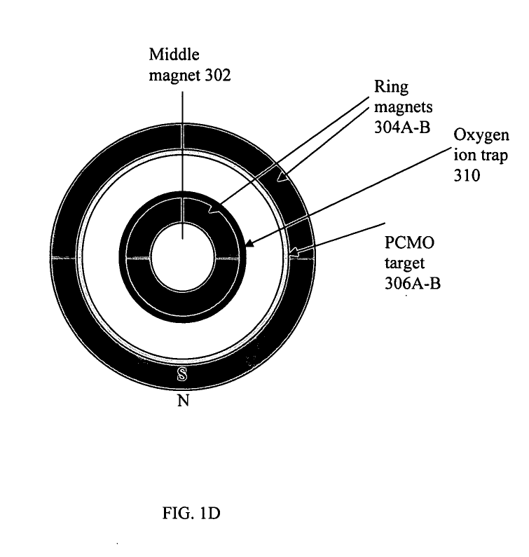

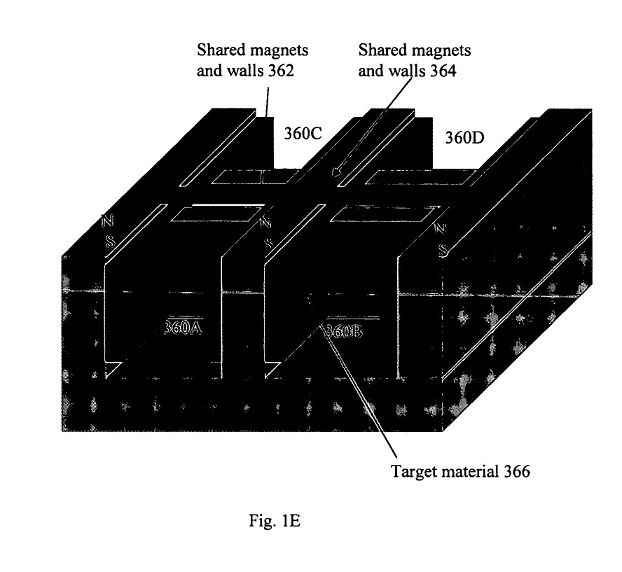

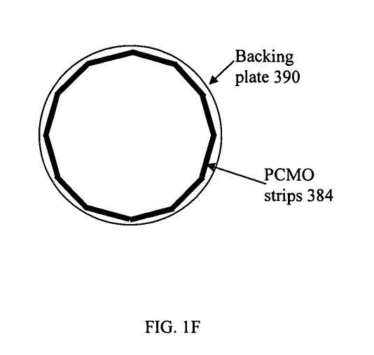

FIG. 1A shows one embodiment of a reactor 10. The reactor 10 includes a metal chamber 14 that is electrically grounded. A wafer or substrate 22 to be sputter coated is supported on a pedestal electrode 24 in opposition to the target 16. An electrical bias source 26 is connected to the pedestal electrode 24. Preferably, the bias source 26 is an RF bias source coupled to the pedestal electrode 24 through an isolation capacitor. Such bias source produces a negative DC self-bias VB on the pedestal electrode 24 on the order of tens of volts. A working gas such as argon is supplied from a gas source 28 through a mass flow controller 30 and thence through a gas inlet 32 into the chamber. A vacuum pump system 34 pumps the chamber through a pumping port 36.

The FTS unit is positioned to face the wafer 22 and has a plurality of magnets 102, 104, 106, and 108 which are part of two facing magnetrons. A first target 110 is positioned between magnets 102 and 104, while a second target 120 is positioned between magnets 106 and 108. The first and second targets 110 and 120 define an electron confining region 130.

The two facing magnetrons are elongated resulting in a rectangular configuration. The rectangular configuration is bent into a doughnut shape by uniting the two ends. Thus the system has two bands of facing magnetrons, one inside the other, as shown in FIG. 1B. By adding magnets of opposite polarity behind the outer and inner target bands, a barrel shaped magnetic field is developed. Thus, on a local scale, the magnetic field is identical to the conventional FTS configuration. The pressure and electric field are identical as well.

A power supply 140 is connected to the magnets 102-108 and targets 110-120 so that positive charges are attracted to the second target 120. During operation, particles are sputtered onto a substrate 150 which, in one embodiment where the targets 110 and 120 are laterally positioned, is vertically positioned relative to the lateral targets 110 and 120. The substrate 150 is arranged to be perpendicular to the planes of the targets 110 and 120. A substrate holder 152 supports the substrate 150.

The targets 110 and 120 are positioned in the reactor 10 to define the plasma confining region 130 therebetween. Magnetic fields are then generated to cover vertically the outside of the space between facing target planes by the arrangement of magnets installed in touch with the backside planes of facing targets 110 and 120. The facing targets 110 and 120 are used a cathode, and the shield plates are used as an anode, and the cathode/anode are connected to output terminals of the direct current (DC) power supply 140. The vacuum vessel and the shield plates are also connected to the anode.

Under pressure, sputtering plasma is formed in the space 130 between the facing targets 110 and 120 while power from the power source is applied. Since magnetic fields are generated around the peripheral area extending in a direction perpendicular to the surfaces of facing targets 110 and 120, highly energized electrons sputtered from surfaces of the facing targets 110 and 120 are confined in the space between facing targets 110 and 120 to cause increased ionized gases by collision in the space 130. The ionization rate of the sputtering gases corresponds to the deposition rate of thin films on the substrate 22, then, high rate deposition is realized due to the confinement of electrons in the space 130 between the facing targets. The substrate 22 is arranged so as to be isolated from the plasma space between the facing targets 110 and 120.

Film deposition on the substrate 22 is processed at a low temperature range due to a very small number of impingement of plasma from the plasma space and small amount of thermal radiation from the target planes. A typical facing target type of sputtering method has superior properties of depositing ferromagnetic materials at high rate deposition and low substrate temperature in comparison with a magnetron sputtering method. When sufficient target voltage VT is applied, plasma is excited from the argon. The chamber enclosure is grounded. The RF power supply 26 to the chuck or pedestal 24 causes an effective DC ‘back-bias’ between the wafer and the chamber. This bias is negative, so it repels the low-velocity electrons.

The efficiency of the facing magnetron deposition can be further increased by incorporating a secondary additional magnetron excitation system (238) with a separate power supply 237 that increases the number of positive ions that are then accelerated into the wafer surface by the back bias.

FIG. 1B shows in more detail the magnetron structure that allows the configuration to be symmetrical and results in a small and uniform source. In this embodiment, an elongated central or middle magnet 302 is encircled by an inner ring magnet 304A. An inner target ring 306A encircles the ring magnet 304A and faces a second target ring 306B. The second target ring 306B is in turn encircled by an outer ring magnet 304B. The arrangement forms a “doughnut.”

Although FIG. 1 shows a single doughnut, a plurality of doughnuts (one doughnut inside another doughnut) can be used. Thus, for a double doughnut, four magnets and four circular target plates are used. For a triple doughnut, six magnets and six circular target plates can be used. FIG. 1C shows the system of FIG. 1B with a plurality of moving magnets 308A-308B.

During operation, a parallel magnetic field having a portion parallel to the surface of the cylindrical target rings 306A-B effect generation of a magnetron-mode electromagnetic field in the vicinity of the surface over the entire periphery of each of the facing targets. Also, a magnetic field extending between the facing targets 306A-B causes facing-mode electromagnetic fields within the space between the facing targets 306A-B. As a result, high-density plasma is generated over the entire surface of each of the targets 306A-B using a small and uniform source.

FIG. 1D shows the system of FIG. 1B with an oxygen ion trap 310 in place of the target 306A. The oxygen ion trap 310 traps oxygen in a three-dimensional quadrupole electric field generated basically by combining an RF electric field and a DC electric field. The ion trap device is constructed by cylindrical and disc electrodes in which an ion trapping space is created around the center of the space surrounded by the electrodes. In these constructions, the electrodes are composed of a ring electrode, and two end cap electrodes placed at both ends of the ring electrodes, wherein the RF voltage is normally applied to the ring electrode. In either electrode construction, the mass to charge ratio (m/e) of an ion determines whether the ion is trapped in the trapping space in a stable manner, or whether its movement becomes unstable and it collides with the electrodes, or it is ejected from an opening of the electrodes.

FIG. 1E shows a cross-type facing magnetron. In this embodiment, a plurality of square FTS source sub-chambers 360A, 360B, 360C, and 360D are positioned adjacent each other and share walls and magnets 362 and 364. The arrangement of FIG. 1E allows a four fold pattern which will increase coverage on target material 366. For example, a conventional square FTS apparatus with 4″ target plate separation can cover about 2″ of a 4″ wafer. The shared wall arrangement of FIG. 1E can cover a larger area such as 12″, for example, while increasing uniformity. Each sub-chamber yields a cosine distribution, which is additive since the chambers are in close proximity. By optimizing the exact positions, a smooth distribution will result.

FIG. 1F shows an exemplary embodiment of a target material. The target material is typically a CMO ceramic which is difficult to shape into a circular shape. Therefore the embodiment of FIG. 1F has small rectangular CMO plates or strips 384 which will interlock to approximate a circular shape. The plates or strips 384 have backing plates 390 which is circular in shape.

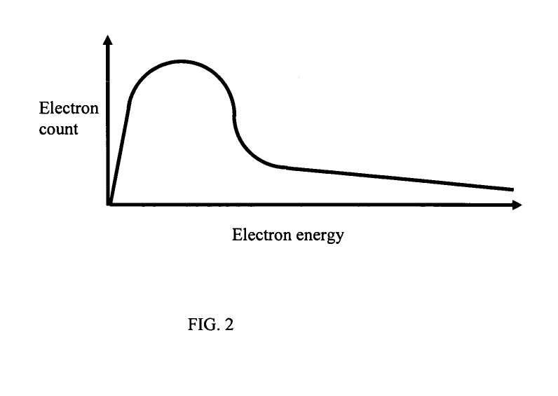

FIG. 2 illustrates an exemplary electron distribution for the apparatus of FIG. 1A. The electron distribution follows a standard Maxwellian curve. Low energy electrons have two characteristics: they are numerous and they tend to have non-elastic collisions with the deposited atoms, resulting in amorphization during deposition. High-energy electrons come through the back-biased shield, but they effectively “bounce” off the atoms without significant energy transfer—these electrons do not affect the way bonds are formed. This is especially true because high energy electrons spend very little time in the vicinity of the atoms, while the low energy electrons spend more time next to the atoms and can interfere with bond formation.

The presence of the large positively biased shield affects the plasma, particularly close to the pedestal electrode 24. As a result, the DC self-bias developed on the pedestal 24, particularly by an RF bias source, may be more positive than for the conventional large grounded shield, that is, less negative since the DC self-bias is negative in typical applications. It is believed that the change in DC self-bias arises from the fact that the positively biased shield drains electrons from the plasma, thereby causing the plasma and hence the pedestal electrode to become more positive.

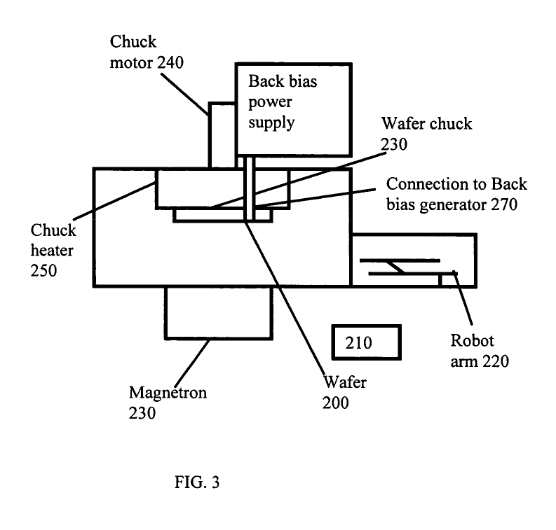

FIG. 3 shows another embodiment of an FTS system. In this embodiment, a wafer 200 is positioned in a chamber 210. The wafer 200 is moved into the chamber 210 using a robot arm 220. The robot arm 220 places the wafer 200 on a wafer chuck 230. The wafer chuck 230 is moved by a chuck motor 240. One or more chuck heaters 250 heats the wafer 200 during processing.

Additionally, the wafer 200 is positioned between the heater 250 and a magnetron 260. The magnetron 260 serves as highly efficient sources of microwave energy. In one embodiment, microwave magnetrons employ a constant magnetic field to produce a rotating electron space charge. The space charge interacts with a plurality of microwave resonant cavities to generate microwave radiation. One electrical node 270 is provided to a back-bias generator such as the generator 26 of FIG. 1.

In the system of FIG. 3, two target plates are respectively connected and disposed onto two target holders which are fixed to both inner ends of the chamber 210 so as to make the target plates face each other. A pair of permanent magnets are accommodated in the target holders so as to create a magnetic field therebetween substantially perpendicular to the surface of the target plates. The wafer 200 is disposed closely to the magnetic field (which will define a plasma region) so as to preferably face it. The electrons emitted from the both target plates by applying the voltage are confined between the target plates because of the magnetic field to promote the ionization of the inert gas so as to form a plasma region. The positive ions of the inert gas existing in the plasma region are accelerated toward the target plates. The bombardment of the target plates by the accelerated particles of the inert gas and ions thereof causes atoms of the material forming the plates to be emitted. The wafer 200 on which the thin film is to be disposed is placed around the plasma region, so that the bombardment of these high energy particles and ions against the thin film plane is avoided because of effective confinement of the plasma region by the magnetic field. The back-bias RF power supply causes an effective DC ‘back-bias’ between the wafer 200 and the chamber 210. This bias is negative, so it repels the low-velocity electrons. By also moving the magnetron or chuck vertically with motor 260 such that the distance between them is changed during deposition, the uniformity of the magnetic field can further be increased.

It is to be understood that various terms employed in the description herein are interchangeable. Accordingly, the above description of the invention is illustrative and not limiting. Further modifications will be apparent to one of ordinary skill in the art in light of this disclosure.

The invention has been described in terms of specific examples which are illustrative only and are not to be construed as limiting. The invention may be implemented in digital electronic circuitry or in computer hardware, firmware, software, or in combinations of them.

Apparatus of the invention for controlling the fabrication equipment may be implemented in a computer program product tangibly embodied in a machine-readable storage device for execution by a computer processor; and method steps of the invention may be performed by a computer processor executing a program to perform functions of the invention by operating on input data and generating output. Suitable processors include, by way of example, both general and special purpose microprocessors. Storage devices suitable for tangibly embodying computer program instructions include all forms of non-volatile memory including, but not limited to: semiconductor memory devices such as EPROM, EEPROM, and flash devices; magnetic disks (fixed, floppy, and removable); other magnetic media such as tape; optical media such as CD-ROM disks; and magneto-optic devices. Any of the foregoing may be supplemented by, or incorporated in, specially-designed application-specific integrated circuits (ASICs) or suitably programmed field programmable gate arrays (FPGAs).

While the preferred forms of the invention have been shown in the drawings and described herein, the invention should not be construed as limited to the specific forms shown and described since variations of the preferred forms will be apparent to those skilled in the art. Thus the scope of the invention is defined by the following claims and their equivalents.

What is claimed is:

1. A face target sputtering apparatus to fabricate semiconductors, comprising:
an air-tight chamber in which an inert gas is admittable and exhaustible;
a first cylindrical target plate in the chamber;
inner and outer cylindrical magnets respectively disposed adjacent to the cylindrical target plate such that magnet poles of different polarities face each other across said plasma region thereby to establish a magnetic field covering the target plate; and
a substrate holder adapted to hold a substrate on which an alloyed thin film is to be deposited.

2. The apparatus of claim 1, comprising a plurality of opposing magnets moving around the outer cylindrical magnet.

3. The apparatus of claim 1, comprising a second cylindrical target plate facing the first cylindrical target plate.

4. The apparatus of claim 1, comprising a central magnet positioned at the center of the inner and outer cylindrical magnets.

5. The apparatus of claim 4, wherein the central magnet is elongated.

6. The apparatus of claim 1, comprising a back-bias power supply coupled to the substrate holder, wherein the substrate is selectively back-biased prior to face target sputtering with a metal to form a pattern on the layer.

7. The apparatus of claim 1, comprising forming a metal including platinum.

8. The apparatus of claim 7, wherein the platinum is sputtered on the layer.

9. The apparatus of claim 1, comprising a negative ion trap positioned between the outer ring magnet and the target plate.

10. The apparatus of claim 1, wherein the target is one of: a cross-shaped target and a circular target.

11. The apparatus of claim 1, wherein the layer is a PCMO layer.

12. The apparatus of claim 9, wherein each plate comprises a CMO ceramic.

13. The apparatus of claim 9, where in each plate is a rectangular CMO plate.

14. The apparatus of claim 1, comprising one or more strips which interlocks to approximate a circular shape.

15. The apparatus of claim 13, wherein the strips have a backing plate for cooling and electrode attachment.

16. The apparatus of claim 1, comprising a water-cooling system in a center and an outer side.

17. The apparatus of claim 1, comprising a barrel-shaped magnetic field between the outer and inner magnet plates

18. The apparatus of claim 1, comprising targets at an oblique angle to the chuck.

19. The apparatus of claim 1, comprising an additional electron-ion magnetron excitation coil to increase the number of positive deposited ions above the wafer

20. The apparatus of claim 1, comprising a mechanism to move the magnetron or the chuck vertically during deposition to achieve a more uniform deposition.

21. The apparatus of claim 1, comprising a plurality of concentric magnets and circular target plates to form multiple doughnuts.
